(19) United States
(12) Patent Application Publication
(10) Pub. No.: US 2018/0321424 A1
(43) Pub. Date: Nov. 8, 2018

(54) METHOD FOR THE STRUCTURING OF A SUBSTRATE SURFACE

(71) Applicant: Fraunhofer-Gesellschaft zur Förderung der angewandten Forschung e.V., Munich (DE)

(72) Inventors: Cindy Steiner, Dresden (DE); Juliane Fichtner, Dresden (DE); Steffen Günther, Dresden (DE); Volker Kirchhoff, Wehlen (DE)

(73) Assignee: Fraunhofer-Gesellschaft zur Förderung der angewandten Forschung e.V., Munich (DE)

(21) Appl. No.: 15/968,237

(22) Filed: May 1, 2018

(30) Foreign Application Priority Data
May 2, 2017 (DE) 10 2017 109 386.9

(51) Int. Cl. G02B 1/12; H01J 37/305; G02B 1/11; B05D 3/06; B05D 3/14

(52) U.S. Cl. CPC G02B 1/12; H01J 37/3056; H01L 31/02168; B05D 3/06; B05D 3/145; G02B 1/11

(57) ABSTRACT

A method for the production of nanoscopic and/or microscopic surface structures on a flat substrate is provided, wherein the surface structure of the substrate is changed through the use of an ion etching process. First, a coating that features a boundary surface-active substance with a concentration of 0.01 to 5 percent by weight is applied to the substrate. The coating applied to the substrate is subsequently transformed into a solid form, and the ion etching process is then performed.

### CROSS-REFERENCE TO RELATED APPLICATIONS

This application claims priority under 35 USC § 119 to Germany patent application DE 10 2017 109 386.9 filed May 2, 2017, the entire contents of which is hereby incorporated by reference.

### BRIEF DESCRIPTION OF THE DRAWINGS

The embodiments may be better understood with reference to the following drawings and description. The components in the figures are not necessarily to scale.

Moreover, in the FIGURES, like-referenced numerals designate corresponding parts throughout the different views.

FIG. 1 illustrates three electron microscopic images of plasma etched coating surfaces.

### DETAILED DESCRIPTION

Flat materials, i.e. materials that feature a very large surface compared to their thickness, such as discs or strips made of a polymer, a metal, or glass, often feature a very smooth surface. These surfaces must sometimes be roughened and structured for further use in technical products at the nanoscopic and microscopic scale. In the following, structures are understood to be at the nanoscopic scale when they feature measurements smaller than 1 μm with respect to their width and distance to one another. Accordingly, structures are understood to be at the microscopic scale when they feature measurements smaller than 1 mm and greater than or equal to 1 μm with respect to their width and distance to one another. In the following, these dimensions will generally be referred to as structural size. The roughening of a surface can be useful, for example, in order to attain an optical anti-reflection coating.

In Schönberger, W. et al., Large-area fabrication of stochastic nano-structures on polymer webs by ion and plasma treatment, Surface & Coatings Technology, Vol. 205 (2011), pgs. 495-497 (hereinafter referred to as “0”), an exemplary method is presented in which a transparent polymer is roughened nanoscopically on its surface by way of a plasma etching process. A porous surface is thereby formed, which causes a gradual transition from the optical refractive index of the polymer to the surrounding medium. In doing so, the optical reflection on this boundary surface is reduced over a broad spectral range. The result is an increased light transmission. An additional advantage is the random, stochastic character of the structuring. Repetitive patterns, which could potentially lead to a diffraction phenomenon, do not appear. The disadvantage of this method is the limitation to polymer materials whose surfaces can be roughened.

The method described in Collaud Coen, M. et al., Modification of the micro and nanotopography of several polymers by plasma treatments, Applied Surface Science, Vol. 207 (2003) pgs. 276-286, features similar disadvantages. The process described is slow, costly, and limited to stationary applications. A dynamic application, that is to say an application on moving substrates, is therefore impossible. Further, a major disadvantage in this method is that work must be performed with a so-called bias. This means that, because of an additional technical device, an electric potential, which prepares the energy for the ions from the plasma that are used for the roughening, must be applied to the substrate to be roughened.

In Schulz U. et al., Anti-reflection of transparent polymers by advanced plasma etching procedures, Optics Express, Vol. 15, No. 20 (2007), pgs. 13108-13113, an additional modification of the process from 0 is described. By adding a very thin and non-closed material layer in the region of a few nanometers of thickness, the formation of the structures is influenced with respect to size and form. However, this process does not overcome the limitation to polymer materials.

In order to equip any desired material type with a structured surface, there is the possibility of applying a coating to these materials, structuring their surfaces while still in a liquid state, and then “freezing” this structure in the cross-linking step of the coating. For example, such a method is described in Bauer F. et al., UV curing and matting of acrylate nanocomposite coatings by 172 nm excimer irradiation in Progress, Organic Coatings, Vol. 64, No. 4, (2009), pgs. 474-481. Here, in a first radiation step, a coating that is sensitive to UV radiation is stochastically folded only on the surface at the microscopic level. In a second step, the total coating thickness is transformed into the solid state through the use of a second UV radiator. This is referred to as the cross-linking of the coating. In this method, structural sizes in the microscopic range are generated. However, nanoscopic structural sizes cannot be produced with this method. Therefore, no broadband anti-reflection effect can be achieved with such a method.

Another very costly method for the structuring of surfaces is disclosed in Kooy, N. et al., A review of roll-to-roll nanoimprint lithography, Nanoscale Res Lett., Vol. 9, No. 1 (2014), pg. 320 et seqq. Here, a coating that is sensitive to UV radiation is geometrically deformed by a stamp in its liquid state and then immediately cross-linked without removing the stamp. After the cross-linking of the coating, the stamp is removed, and the formed coating remains as the surface. The stamp needed for this kind of structuring of a surface is very costly to manufacture. Stochastic structures thus cannot be manufactured, and the structures feature repetitions over a certain dimension, because the stamp must be placed repeatedly for the structuring of larger surfaces. Moreover, structure disruptions always appear at the application point, because the stamp cannot be exactly and seamlessly positioned. For changes to the structural sizes, a new stamp must be manufactured each time. This adds time and costs to the process.

The invention is therefore based upon the technical challenge of creating a method for the structuring of surfaces with which the disadvantages of the prior art can be overcome. In particular, the inventive method can make it possible to produce nanoscopic and/or microscopic surface structures on of substrates of various materials, such as metal or glass materials.

In the inventive method for the production of nanoscopic and/or microscopic surface structures on a flat substrate, a coating is first applied to the substrate surface and transformed into a solid form on the substrate surface. In a second step, this solid coating surface is subjected to an ion etching process, through which the surface is roughened and structured. The accelerated ions used in this process are preferably provided by a plasma. An ion etching process in which the ions are generated by means of a plasma is also called a plasma etching process. The key idea of the invention is adding a chemical additive in the form of a boundary surface-active substance to the liquid coating before the application to the substrate. The boundary surface-active substance may be dissolved or dispersed in the liquid coating. Here, the concentration and the type of the boundary surface-active substance governs how the structure will be formed in the later plasma etching process with respect to porosity, structural size, effective surface, etc. Materials are understood to be boundary surface-active substances when they accumulate on phase boundaries and reduce the surface tension and the boundary surface tension between two phases.

The coating to be used is of a liquid nature. Through chemical or physical processes, it is converted into a consistent, solid film covering a large surface area. An important component of the liquid coating is a film former, which is the main component of the solid layer that forms later. In order to adjust the viscosity of the liquid coating, solvents or reactive thinners can be added to the liquid film former. The processability of the coating is thereby determined to a large degree and can be adjusted by the type and concentration of the solvent and reactive thinner through various methods of liquid coating application. Further components of the coating can be pigments or other solid filling materials. Here, coatings that are solvent-free are advantageous. The environmental burden is thereby drastically reduced. Radiation cross-linked coatings that are acrylate-based are especially advantageous. Highly efficient and highly productive methods of radiation cross-linking can thus be employed. Moreover, urethane acrylate-based coatings feature sufficient stability against the effects of weather and can thus be used for applications outdoors.

In addition to liquid coatings, the use of a powder coating is also conceivable. Here, the adding of the chemical additive takes place during the synthesis of the powder particles.

As a chemical additive for the adjusting of the structures formed in the subsequent plasma etching process, a boundary surface-active substance should be chosen, because this ensures that this substance will have its effect primarily on the surface of the coating. The concentration of the additive should lie between 0.01 percent by weight and 5 percent by weight. The change of the volume properties of the coating is thus kept at a minimum. A concentration range of 0.05 percent by weight to 3 percent by weight was shown to be especially advantageous for the boundary surface-active substance. This results in a large range of adjustable structural sizes in the subsequent plasma etching process, as well as a nearly unchanged property profile of the coating, independent of the presence of the boundary surface-active substance.

The use of a siloxane-based substance as the boundary surface-active substance is advantageous, because the structural sizes can thus be adjusted over a large range of parameters in the later ion etching process. In connection with the use of a radiation-curable coating, in particular, the use of a siloxane-based substance with acrylate functionality is important. This ensures that the substance is chemically bound to the coating in a fixed adhesive manner and is not separated from it by simply mechanical loads, such as wiping. The use of a polyester-modified, multi-acrylic functional polydimethylsiloxane as the boundary surface-active substance proved to be especially advantageous. The bandwidth of attainable structural sizes dependent upon the concentration of this material was observed to be very high, thus ensuring the adjustment of the structures to a great variety of application tasks.

As a method for transforming the coating into a closed, solid form, customary drying methods (infrared drying, thermal drying, microwave, or baking) or methods of radiation cross-linking (electron radiation, UV radiation, LED UV radiation, flash lamp radiation, laser radiation) or combinations of the two can be used. The methods of radiation cross-linking are especially advantageous, because the use of the solvents in the coating can be avoided here. The electron radiation is considered especially advantageous, because a thermal influencing of the material is further minimized, and a very high productivity can be achieved.

For the application of the coating to the material surface, all customary methods for large-surface application are suitable. For example, this could be a roller coating, a doctor blade coating, a spray coating, or a coating by way of slotted nozzle. The slotted nozzle coating has proven to be especially advantageous, because it can apply the coating very evenly over a large breadth and without touching the material surface.

The invention is described below using an exemplary embodiment.

For this purpose, three different sections of a PET slide (type: Melinex® 401, 50 μm thick) were each coated with a 20 μm thick coating. The coating was performed with a spiral doctor blade. Subsequently, the coating on the three slide sections was cross-linked through electron radiation, wherein a radiation dose of 45 kGy was used under inert conditions (<200 ppm oxygen). The three sections of the slide were coated with three different coating formulas. For the first slide, a coating A was made of 52.8% aliphatic urethane acrylate and 47.2% 1.6 hexanediol diacrylate. For the coating of the second slide section, a coating B was made, which consists of coating A, with replacement of 0.1 percent by weight with polyester-modified, acrylate functional polydimethylsiloxane. For the coating of the third slide section, a coating C was manufactured, which consists of coating A, with replacement of 3 percent by weight with polyester-modified, acrylate functional polydimethylsiloxane.

After the coating and cross-linking of the three slide sections with the various coatings A, B, and C, the coatings were subsequently ion etched. The etching was performed using ions from an oxygen plasma via a double magnetron, through the use of aluminum targets with an oxygen gas flow of 200 sccm, a process pressure of 0.3 Pa, and a power density on the target of 3.6 W/cm². The process data of the double magnetron was adjusted such that as little sputtering erosion as possible is produced on the aluminum target. In the inventive method, a plasma-producing magnetron functions primarily for the production of a plasma and not for the production of coat-forming particles arising from the magnetron target.

Subsequently, the manufactured samples are characterized with respect to various properties. The optical transmission of the three slide sections (hereinafter also referred to as “samples”) before and after the plasma etching step was spectrally measured over a wavelength of 250 nm to 2500 nm. From the spectrum, the visual transmission was calculated by weighting with the photopic sensitivity of the human eye. Subsequently, the transmission change of the samples that was caused by the plasma etching set was calculated. No difference was observed between the samples from coating A and coating B. Both equally showed an absolute transmission increase by 0.8%. By contrast, the sample from coating C showed an absolute transmission gain of 1.1%. Not only was the transmission increase highest for coating C, but so was its absolute transmission.

The effective surface (also called inner surface or specific surface) was determined on the etched samples. In doing so, it was determined how strongly structured or roughened the surface is in comparison to a perfectly flat surface. For coating B, no change of the effective surface was observed in comparison to coating A. However, for coating C, there was a reduced effective surface compared to coating A. In relation to the observation regarding the optical transmission, this is astonishing, because in the case of a less strongly structured surface, one would expect a transmission decrease instead of a transmission increase. The high optical transmission with simultaneously decreased effective surface is advantageous, for example, for optical devices that lie in a haptic sphere of influence. Dirtying by finger oils should be less easily “smudged” by the less strongly structured surface of coating C. It can thus be demonstrated that the inventive process is suitable for changing the specific surface of substrates.

The durability against mechanical loads (abrasion) was determined by a Taber Abraser Test based upon DIN 52 347. Here, two friction rollers (CS10F) rub 100 times on the respective sample surface with a load of 250 g. After defined intervals, the loss of gloss on the samples was measured as a standard for the change of the surface by the mechanical influence compared to the starting situation, through reflection measurement at an angle of 60°. Further, light microscope images were produced in order to investigate the surface for scratches and other influence patterns. The loss of gloss was greatest in the sample from coating A. The smallest loss of gloss was detected in the sample from coating B. The light microscopic images showed the smallest scratch densities and lowest scratch depths. The mere presence of the chemical additive in the form of a boundary surface-active substance thus increased the abrasion durability for coating B and coating C, however, optimization is still possible with respect to its concentration depending upon the primarily present load type.

The linking of the plasma etched coating surface via water was investigated by way of a contact angle measurement. This revealed a comparable contact angle for coating A and coating B, while coating C had a smaller contact angle. For applications outdoors, in particular, a higher contact angle is positive, because the self-cleaning of the surfaces is thereby improved. Coating B now combines the property of a high contact angle with the lowest loss of gloss. Through the plasma etched coating B, outdoor optical devices (solar modules) can, for example, be protected against dirtying and mechanical influence.

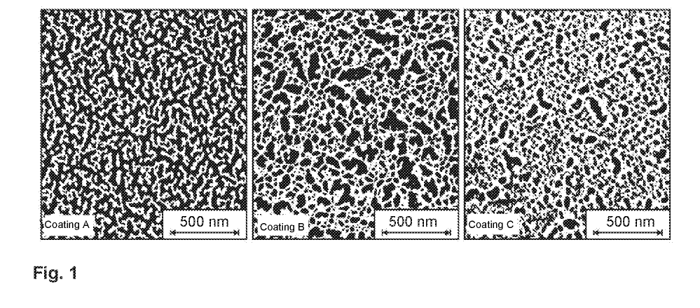

Using raster electron microscopic images of the plasma etched coating surfaces (shown in FIG. 1), great differences can be observed in the structures of coatings A, B, and C. The regions that lead into the material are hereinafter referred to as pores. Coating A shows structures that jut out of the surface individually. The pores in coating A are not isolated but are rather largely joined to one another. A network of pores is thus formed. By contrast, coating B and coating C show structures that are joined in a networked manner, and the pores are isolated. Depending upon the various application cases, the structure types can therefore be adjusted over a broad range of characteristics through variation of the chemical additive.

Taking the surface of the pores in relation to the total projected surface gives the pore surface share. Coating A features the greatest pore surface share. Coating B has an average pore surface share, and coating C has the smallest of the three samples. The pore surface share can also be changed by the chemical additive.

The various test variables recorded show differing dependencies on the chemical additive. This results in a high potential for optimization possibilities in order to be able to adjust the various parameters for different applications.

To clarify the use of and to hereby provide notice to the public, the phrases “at least one of <A>, <B>, . . . and <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed.

1. A method for the production of nanoscopic and/or microscopic surface structures on a flat substrate by an ion etching process, the method comprising:
applying a coating having a boundary surface-active substance with a concentration of 0.01 to 5 percent to the substrate;
converting the coating previously applied to the substrate into a solid form; and
performing the ion etching process after the coating is converted into the solid form.

2. The method according to claim 1, wherein the coating is a boundary surface-active substance having a concentration of 0.1 to 3 percent by weight.

3. The method according to claim 1, wherein the coating is converted into a solid form through use of radiation cross-links.

4. The method according to claim 3, wherein an electron radiation is used for the cross-linking of the coating.

5. The method according to claim 1, wherein the coating is an acrylate-based coating.

6. The method according to claim 5, wherein the coating is a urethane acrylate-based coating.

7. The method according to claim 1, wherein a siloxane-based additive is used as the boundary surface-active substance.

8. The method according to claim 7, wherein a polyester modified, multi-acrylic functional polydimethylsiloxane is the boundary surface-active substance.

9. The method according to claim 1, wherein the ion etching process includes a plasma etching process.

10. The method according to claim 9, wherein the plasma etching process includes producing an oxygen plasma by a magnetron.

11. The method according to claim 1, wherein the coating is applied to the substrate through use of slotted nozzle application.
